(19) United States
(12) Patent Application Publication
(10) Pub. No.: US 2004/0094195 A1
(43) Pub. Date: May 20, 2004

(54) Solar cell connector having a frame-shaped compensation section and method of producing same

(76) Inventor: Gunter Kuechler, Haselau (DE)

Correspondence Address: CROWELL & MORING LLP, INTELLECTUAL PROPERTY GROUP, P.O. BOX 14300, WASHINGTON, DC, 20044-4300, US

(21) Appl. No.: 10/630,915

(22) Filed: Jul. 31, 2003

(30) Foreign Application Priority Data
Jul. 31, 2002 (DE) 102 35 048.5

(51) Int. Cl. H01L 31/00

(52) U.S. Cl. 136/256

(57) ABSTRACT

A solar cell connector which has at least one compensation section, the compensation section having a frame-shaped structure, and a method is provided for producing the solar cell connector. The frame-shaped structure compensation section includes only one recess.

### BACKGROUND AND SUMMARY OF THE INVENTION

This application claims the priority of Application No. 102 35 048.5, filed Jul. 31, 2002, in Germany, the disclosure of which is expressly incorporated by reference herein.

The present invention relates to a solar cell connector having at least one compensation section. Such solar connectors are known from the prior art, for example, from European Patent Document EP 1 128 445 (corresponding U.S. Pat. No. 6,359,209) and German Patent Document DE 43 30 282 (corresponding U.S. Pat. No. 5,430,616).

European Patent Document EP 1 128 445 (corresponding U.S. Pat. No. 6,359,209) describes a largely planar in-plane solar cell connector having a compensation section which has a periodic net-shaped pattern and is used as a tension reduction section.

German Patent Document DE 43 30 282 (corresponding U.S. Pat. No. 5,430,616) describes planar solar cell connectors which, as a tension reduction section, have a compensation section with several open slots and/or circular notches, the compensation section being used for absorbing a displacement generated between mutually connected solar cell elements and thereby for the reduction of occurring tensions in the solar connector.

However, this prior art has the disadvantage that a simple and cost-effective manufacturing of high-expenditure or even filigree structures of the compensation sections is not possible and that, for example, a filigree network structure can easily be unintentionally deformed and, in the case of open slots and notches, a deformation of the solar cell connector can take place during the machining with material becoming caught.

It is therefore an object of the present invention to provide a robust solar cell connector which can nevertheless be produced in a cost effective manner by means of simple devices. This object is achieved according to preferred embodiments of the invention by providing a solar cell connector having at least one compensation section, wherein the compensation section has a frame shaped structure. This object is also achieved according to preferred embodiments of the invention by providing a method of producing a solar cell arrangement, comprising providing a metal strip, forming a solar cell connector structure from the metal strip with first and second connection areas and at least one frame-shaped compensation section arranged between the connection areas, connecting the first connection with at least a first solar cell, and connecting the second connection area with at least a second solar cell.

The present invention comprises a solar cell connector having at least one compensation section, in which case the compensation section has a frame-shaped structure. Because of its simple structure, such a frame-shaped structure can be produced by simple manufacturing processes, such as stamping, etching or eroding, and, because of its frame shape, it is more robust than network structures or slotted connector structures.

The entire solar cell connector and/or the particular frame-shaped structure may basically have any arbitrary material cross-section. It may, for example, be provided that the entire solar cell connector has a band-shaped construction. Such a band-shaped structure can particularly easily be produced by cost-effective material processing methods. However, in partial areas of the solar cell connector, the structure may also be different than purely band-shaped. Thus, areas of the solar cell connector which are, for example, to be more reinforced, may have a slightly arched structure.

In particular, it is provided according to certain preferred embodiments of the invention that, as a result of the band-shaped structure of the solar cell connector, a surface is defined and the frame-shaped structure of the compensation section is formed by precisely one recess closed in the defined surface. In this case, the defined surface does not have to extend in a plane but may have a three-dimensional shape according to certain preferred embodiments of the invention; that is, the solar cell connector does not have to have a purely planar construction, but the, for example, band-shaped structure of the solar cell connector may have a three-dimensional shape. However, in contrast to the prior art, the solar cell connector only has precisely one recess instead of, for example, a network structure. Furthermore, the recess is closed in the defined surface and is not constructed as an open slot or notch.

Any suitable shaping may basically be provided for the frame-shaped structure. A first further development of the invention provides that the frame-shaped structure has an oval construction. This is particularly advantageous because, in the case of such a structure, special tension peaks can occur at virtually no point. As a special design of the oval structure, it may be provided that the frame-shaped structure has a round construction.

However, if the occurrence of possible tension peaks is not that problematic, the frame-shaped structure may also have a cornered construction. Thus, the frame-shaped structure may, for example, have a triangular, a square or any other polygonal shape.

Basically, any suitable material may be provided for the manufacturing of the solar cell connector. However, the solar cell connector preferably consists of a precious metal or another conductive material with a precious-metal coating. Particularly gold or silver may be used as the precious metal. A subgroup element may be used as the conductive material, for example, a conductive material of the sixth subgroup, such a molybdenum or another subgroup element with comparable material characteristics, such as an element of the sixth subgroup.

Another object of the present invention is a method of producing a solar cell arrangement, characterized by the following steps:

Providing a metal strip,

stamping out a solar cell connector structure with first and second connection areas and at least one frame-shaped compensation section arranged between the connection areas,

connecting the first connection area with at least a first solar cell and connecting the second connection area with at least a second solar cell.

By means of such a method, a solar cell connector with an advantageous frame-shaped compensation section can be produced in a particularly simple manner. In this regard, reference is made to the above-mentioned advantages.

Within the scope of this process, the solar cell connector can be produced particularly in a construction described above by means of the arrangement according to the invention. Within the scope of this process, individual arrangement characteristics or all of the above-mentioned arrangement characteristics are implemented in corresponding manufacturing steps.

In the following, special embodiments of the present invention are explained by means of FIGS. 1 to 5.

Other objects, advantages and novel features of the present invention will become apparent from the following detailed description of the invention when considered in conjunction with the accompanying drawings.

### BRIEF DESCRIPTION OF THE DRAWINGS

FIG. 1 is a view of a planar solar cell connector with an oval frame-shaped compensation section according to certain preferred embodiments of the invention;

FIG. 2 is a lateral view of an alternative embodiment of a planar solar cell connector according to FIG. 1;

FIG. 3 is a view of a planar solar cell connector having a round frame-shaped compensation section constructed according to another preferred embodiment of the invention;

FIG. 4 is a view of a planar solar cell connector having a triangular frame-shaped compensation section constructed according to another preferred embodiment of the invention; and

FIG. 5 is a view of a planar solar cell connector having a square frame-shaped compensation section constructed according to another preferred embodiment of the invention.

### DETAILED DESCRIPTION OF THE DRAWINGS

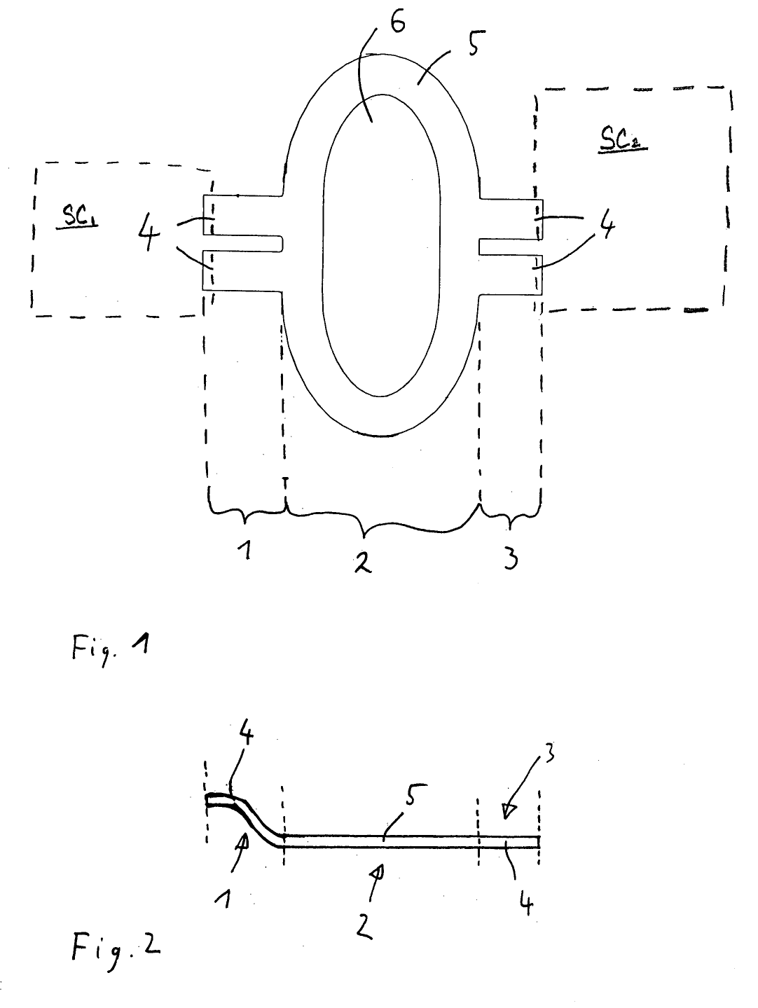

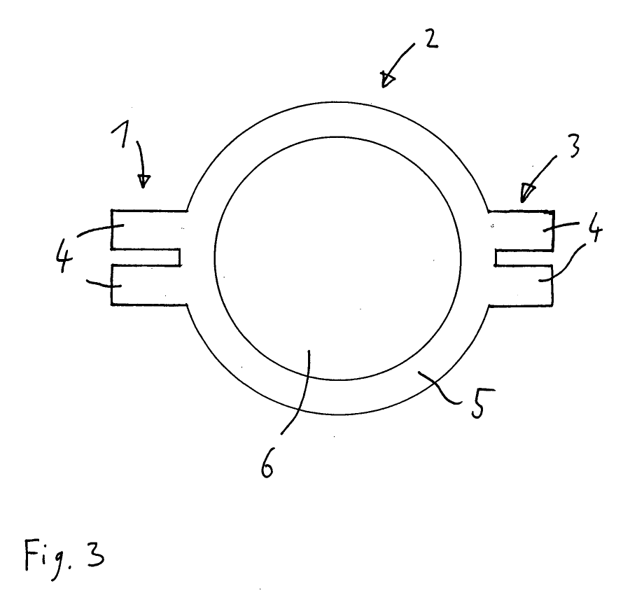

FIG. 1 shows a band-shaped solar cell connector which has the following: A first connection area 1 for contacting at least a first solar cell (SC1 illustrated only schematically in dash lines), a compensation section 2 for the tension compensation for mechanical, thermomechanical or other tensions, and a second connection area 3 for contacting at least a second solar cell (SC2 illustrated only schematically in dash lines). Such a solar cell connector may be produced, for example, from a metal strip by means of corresponding material processing steps. The connection areas 1, 3 may be formed in each case by one or several connection strips 4. The compensation section 2 has a frame-shaped structure 5 and has the shape of an oval. By means of its dimension, the band-shaped solar cell connector defines a surface which, in the case of a planar construction of the solar cell connector, is situated in a plane. As an alternative, the solar cell connector may also be have an appropriate three-dimensional shape, as schematically illustrated in FIG. 2 in a lateral view of the solar cell connector. Starting from a planar shape corresponding to FIG. 1, this shape can be achieved by a further forming of the solar cell connector. The solar cell connector may also have a three-dimensional shape deviating from FIG. 2. A three-dimensional shape as in FIG. 2 may also be the result of the fact that the solar cell connector is used for the connection between a front side of the first solar cell and a back side of a second adjacent solar cell, in which case the connection area 1 is correspondingly bent up, but the compensation section 2 remains plane. In the case of such an alternative, three-dimensionally shaped construction of the solar cell connector, the surface defined by the solar cell connector is no longer situated in a plane. In each case, the solar cell connector has exactly one recess 6 closed in the defined surface, as illustrated by FIG. 1; that is, in the defined surface, the recess 6 has a closed bordering. The same applies to the embodiments according to FIGS. 3 to 5. Specifically such a structure can be produced in a very simple manner without having to observe high manufacturing tolerances, and, while the tension compensation characteristics are good, nevertheless results in a robust structure.

FIG. 3 shows a special shape of a solar cell connector with a circular compensation section 2 as a special construction of an oval. The meaning of the reference numbers is analogous to FIG. 1. As illustrated by FIGS. 1 and 3, in the case of an oval shape, the compensation section has no corners; all areas of the compensation section 2 are of equal quality relative to the material. As a result, mainly the probability of the occurrence of local tension peaks or of locally different deformation characteristics is very low.

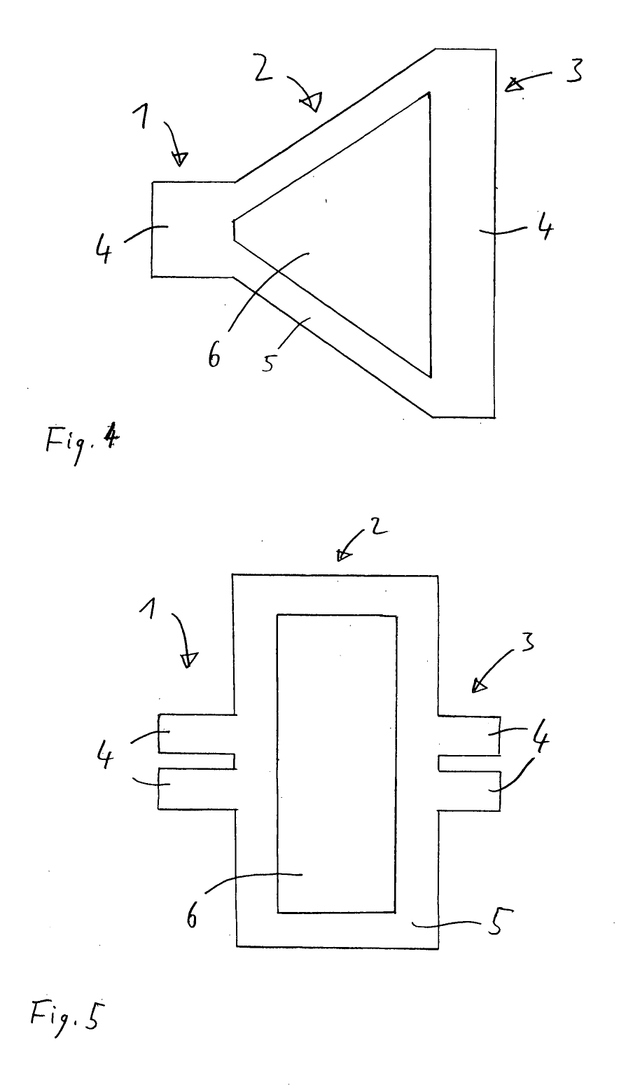

FIGS. 4 and 5 illustrate special constructions of an angular compensation section 2 between two connection areas 1 and 3. Here, particularly the embodiment according to FIG. 4 with a triangular compensation section 2 makes it possible that, in a simple manner, connection strips 4 of different sizes can be provided in the connection areas 1 and 3 while the structure of the entire solar cell connector is simple. In the case of a structure according to FIG. 5, the number and/or width of the connection strips 4 can be varied within wide ranges particularly along the sides of the compensation section 2, without the requirement of having to make significant changes on the overall structure of the solar cell connector.

The above-mentioned solar cell connectors may consist in their entirely or only in partial areas of silver or gold or of, for example, a silver-plated or gold-plate molybdenum or of another comparable conductive material with a silver or gold coating.

The solar cell connectors illustrated here may be produced in a simple and cost-effective manner by stamping, etching or eroding. No particularly high requirements have to be observed with respect to manufacturing tolerances. Another advantage of these solar cell connectors is the fact that, as a result of the frame-shaped structure of the compensation section 2, this area of the solar cell connector has only little material despite a simple structure.

The foregoing disclosure has been set forth merely to illustrate the invention and is not intended to be limiting. Since modifications of the disclosed embodiments incorporating the spirit and substance of the invention may occur to persons skilled in the art, the invention should be constructed to include everything within the scope of the appended claims and equivalents thereof.

What is claimed is:

1. Solar cell connector having at least one compensation section, wherein the compensation section has a frame-shaped structure.

2. Solar cell connector according to claim 1, wherein the solar cell connector has a band-shaped construction.

3. Solar cell connector according to claim 2, wherein the band-shaped structure of the solar cell connector defines a surface, and the frame-shaped structure of the compensation section is formed by exactly one recess closed in the defined surface.

4. Solar cell connector according to claim 1, wherein the frame-shaped structure has an oval construction.

5. Solar cell connector according to claim 3, wherein the frame-shaped structure has an oval construction.

6. Solar cell connector according to claim 4, wherein the frame-shaped structure has a round construction.

7. Solar cell connector according to claim 5, wherein the frame-shaped structure has a round construction.

8. Solar cell connector according to claim 1, wherein the frame-shaped structure has an angular construction.

9. Solar cell connector according to claim 3, wherein the frame-shaped structure has an angular construction.

10. Solar cell connector according to claim 8, wherein the frame-shaped structure has a triangular, a square or a polygonal construction.

11. Solar cell connector according to claim 9, wherein the frame-shaped structure has a triangular, a square or a polygonal construction.

12. Solar cell connector according to claim 1, wherein the connector consists of a precious metal or a conductive material with a precious-metal coating.

13. Solar cell connector according to claim 3, wherein the connector consists of a precious metal or a conductive material with a precious-metal coating.

14. Solar cell connector according to claim 12, wherein gold or silver is provided as the precious metal.

15. Solar cell connector according to claim 13, wherein gold or silver is provided as the precious metal.

16. Solar cell connector according to claim 12, wherein a subgroup element is provided as a conductive material of the connector.

17. Solar cell connector according to claim 1, produced by stamping, etching or eroding.

18. Solar cell connector according to claim 3, produced by stamping, etching or eroding.

19. Method of producing a solar cell arrangement, comprising:
providing a metal strip,
forming a solar cell connector structure from the metal strip with first and second connection areas and at least one frame-shaped compensation section arranged between the connection areas,
connecting the first connection area with at least a first solar cell, and
connecting the second connection area with at least a second solar cell.

20. Method according to claim 19, wherein the solar cell connector has a band-shaped construction.

21. Method according to claim 20, wherein the band-shaped structure of the solar cell connector defines a surface, and the frame-shaped structure of the compensation section is formed by exactly one recess closed in the defined surface.

22. Method according to claim 21, wherein the frame-shaped structure has an oval construction.

23. Method according to claim 21, wherein the frame-shaped structure has a round construction.

24. Method according to claim 21, wherein the frame-shaped structure has an angular construction.

25. Method according to claim 21, wherein the frame-shaped structure has an triangular, a square or a polygonal construction.

26. Method according to claim 21, wherein the connector consists of a precious metal or a conductive material with a precious-metal coating.

27. Method according to claim 19, wherein said forming includes stamping said connector structure out of the metal strip.

28. Method according to claim 19, wherein said forming includes etching.

29. Method according to claim 19, wherein said forming includes eroding.

30. Method according to claim 21, wherein said forming includes stamping said connector structure out of the metal strip.
